(19) United States
(12) Patent Application Publication
(10) Pub. No.: US 2003/0052719 A1
(43) Pub. Date: Mar. 20, 2003

(54) Digital delay line and delay locked loop using the digital delay line

(76) Inventor: Kwang Jin Na, Kyoungki-do (KR)

Correspondence Address: LADAS & PARRY, 224 SOUTH MICHIGAN AVENUE, SUITE 1200, CHICAGO, IL, 60604, US

(21) Appl. No.: 10/246,934

(22) Filed: Sep. 19, 2002

(30) Foreign Application Priority Data
Sep. 20, 2001 (KR) 2001-58154
May 13, 2002 (KR) 2002-26188

(51) Int. Cl. H03L 7/06

(52) U.S. Cl. 327/158

(57) ABSTRACT

A digital delay line includes a delay section and a clock providing section. The delay section comprises N (N being a natural number) unit delay elements which are connected in series and each of which is composed of one logic product gate. The clock providing section provides a first clock signal, or a second clock signal having a phase difference of 180° with respect to the first clock signal, to one among the N unit delay elements according to an externally inputted selection signal. The first clock signal is provided to the unit delay elements bearing even numbers, as counted from a clock output terminal, and the second clock signal is provided to the unit delay elements bearing odd numbers. According to the digital delay line, the jitter characteristic of a delay locked loop can be improved, and the area required for designing the digital delay line can be reduced by one-half in comparison to the existing digital delay line.

### BACKGROUND OF THE INVENTION

1. Field of the Invention

The present invention relates generally to a digital delay line and a delay locked loop using the digital delay line, and more particularly to a digital delay line and a delay locked loop using the digital delay line that can simplify the construction of a respective unit delay element constituting the digital delay line and reduce a unit delay in the unit delay element.

2. Description of the Prior Art

As is generally known in memory design, the time required for passing through a clock buffer inside a chip, and among the clock skew components that deteriorate a high-speed data transmission, is important in determining essential timing parameters of a DRAM. Since an external clock is not inputted at the CMOS level, an external clock should be received through the clock buffer. A clock driver circuit having a large driving capacity is required for supplying the clock signal to various internal circuits. Thus, an internal clock signal has a delay in comparison to the external clock signal. Accordingly, a clock access time that is required from the input of the external clock to the output of data, is increased as much as the delay component, and this imposes a burden on the system design so as to make the high-speed operation of the DRAM impossible. A phase locked loop (PLL) or delay locked loop (DLL) may provide a circuit for achieving the high-speed operation of the memory by removing the delay component. In distinction from the PLL, the DLL uses a voltage controlled delay line (VCDL) instead of a voltage controlled oscillator (VCO) of the PLL.

FIG. 1 is a circuit diagram of a conventional digital delay line. As shown in FIG. 1, the conventional digital delay line includes a delay section 103 for delaying a clock signal clk for a predetermined time, and a clock providing section 105 for selectively providing the clock signal to a unit delay element 101 in a specified position of the delay section 103. In FIG. 1, ‘clk’ denotes the clock signal provided from a clock buffer (not shown), and ‘clkout’ denotes the clock signal delayed and outputted through the digital delay line.

The delay section 103 of the conventional digital delay line, as shown in FIG. 1, has a structure in that NAND gates (hereinafter referred to as “delay section NAND gates”) and inverter gates are alternately connected. One delay section NAND gate and one inverter constitute one unit delay element 101, as shown by the broken line. The output of an inverter is provided as an input signal to a subsequent delay section NAND gate of the next stage. The clock providing section 105 includes NAND gates (hereinafter referred to as “clock providing section NAND gates”), the number of which is the same as that of unit delay elements 101 that constitute the delay section 103. For example, each NAND gate 100 in the clock providing section 105 has a corresponding unit delay element 101 in delay section 103, as shown in FIG. 1. Also, other input signals, such as selection signals sel1, sel2, . . . to sel100, for selectively enabling the clock providing section NAND gates, are provided to the input terminals of the corresponding clock providing section NAND gates.

FIG. 2 is a waveform diagram explaining the operation of the conventional digital delay line shown in FIG. 1. Referring to FIG. 2, if the selection signal sell goes to a high level, the clock signal clk is outputted as the clock signal clkout after passing through one NAND gate and one unit delay element. If the selection signal sel2 goes to a high level, the clock signal clk is outputted as the clock signal clkout after passing through one NAND gate and two unit delay elements. The number of unit delay elements that the clock signal clk passes through in case of the high-level selection signal sell is different from that in case of the high-level selection signal sel2. The time required for passing through one unit delay element is called a unit delay (UD), as shown.

As described above, each unit delay element 101 in the conventional digital delay line 103 includes two gates, i.e., one NAND gate and one inverter gate. The jitter characteristic of the delay locked loop using such unit delay elements 101 thereby deteriorates. Also, additional problems arise in the conventional unit delay element 101 because the area required for each element 101 is increased in the design of the digital delay line.

### SUMMARY OF THE INVENTION

Accordingly, the present invention has been made to solve the above-mentioned problems occurring in the prior art, and an object of the present invention is to provide a digital delay line and a delay locked loop using the digital delay line that has unit delay elements of an improved structure capable of improving the jitter characteristic of the delay locked loop.

Another object of the present invention is to provide a digital delay line and a delay locked loop using the digital delay line that has improved unit delay elements capable of reducing the area occupied by the unit delay elements in the design of the digital delay line.

Still another object of the present invention is to provide a digital delay line and a delay locked loop using the digital delay line that has a shorter unit delay time in comparison to the existing delay line.

In order to accomplish this object, a digital delay line of the present invention comprises: a first NAND gate for 2 input of a first clock signal and a first control signal; a second NAND gate for 2 input of output signal of the first NAND gate and high level signal; a first inverter for input of a second control signal; a first NOR gate for 2 input of a second clock signal having a phase difference of 180° and output signal of the first inverter; and a second NOR gate for 2 input of output signal of the second NAND gate and output signal of the first NOR gate.

It is desirable that the present invention further comprises: a third NAND gate for 2 input of a first clock signal and a third control signal; a fourth NAND gate for 2 input of output signal of the third NAND gate and output signal of the second NOR gate; a second inverter for input of a fourth control signal; a third NOR gate for 2 input of the second clock signal and output signal of the second inverter; and a fourth NOR gate for 2 input of output signal of the fourth NAND gate and output signal of the third NOR gate.

It is desirable that rising edge of the first clock signal is the same with falling edge of the second clock signal. And, both the first clock signal and the second clock signal have a duty of 50%. And, the second NAND gate has the same delay time with the second NOR gate. And, the first NAND gate has the same delay time with the first NOR gate.

In another aspect of the present invention, a digital delay line of the present invention comprises: a first inverter for input of a first control signal; a first NOR gate for 2 input of a first clock signal and output signal of the first inverter; a second NOR age for 2 input of output signal of the first NOR gate and low level signal; a first NAND gate for 2 input of a second clock signal having a phase difference of 180° with the first clock signal; and a second NAND gate for 2 input of output signal of the first NAND gate and output signal of the second NOR gate.

### BRIEF DESCRIPTION OF THE DRAWINGS

The above and other objects, features and advantages of the present invention will be more apparent from the following detailed description taken in conjunction with the accompanying drawings, in which:

FIG. 1 is a circuit diagram of a conventional digital delay line.

FIG. 2 is a waveform diagram explaining the operation of the conventional digital delay line shown in FIG. 1.

FIG. 3 is a circuit diagram of a digital delay line according to an embodiment of the present invention.

FIG. 4 is a waveform diagram explaining the operation of the digital delay line of FIG. 3 according to the present invention.

FIG. 5 is a block diagram of a conventional delay locked loop.

FIG. 6 is a block diagram of a delay locked loop according to another embodiment of the present invention.

FIG. 7 is a block diagram illustrating the relationship between a clock signal amplification section (i.e., a portion of a clock buffer) and a duty correction section according to the embodiment of the present invention shown in FIG. 6.

FIG. 8 is a circuit diagram of the clock signal amplification section according to the embodiment of the present invention shown in FIGS. 6 and 7.

FIG. 9 is a circuit diagram of the duty correction section according to any of the embodiments of the present invention.

FIG. 10 is a circuit diagram of a digital delay line according to another embodiment of the present invention.

### DETAILED DESCRIPTION OF THE PREFERRED EMBODIMENTS

Hereinafter, a preferred embodiment of the present invention will be described with reference to the accompanying drawings. In the following description and drawings, the same reference numerals are used to designate the same or similar components, and so repetition of the description on these same or similar components will be omitted.

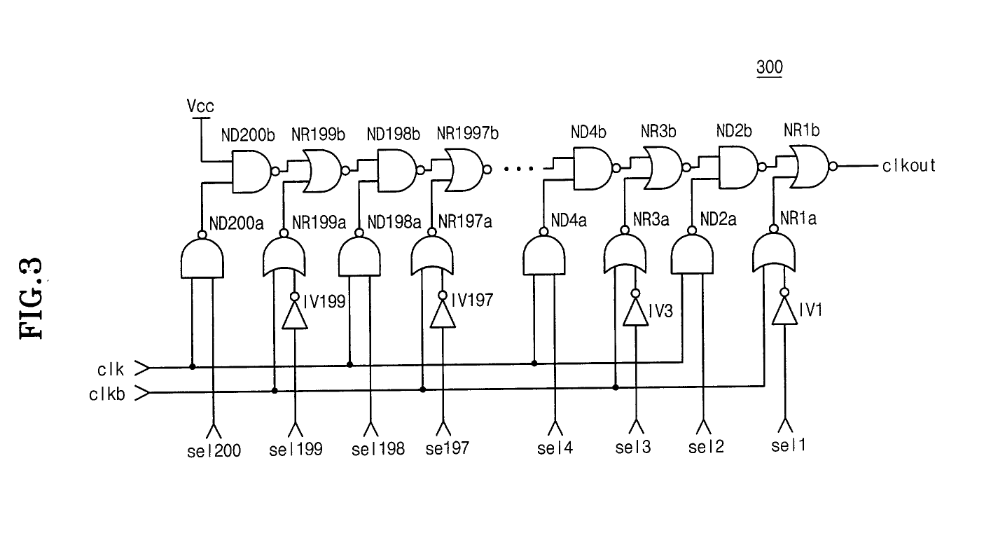

FIG. 3 is a circuit diagram of the digital delay line according to an embodiment of the present invention. As shown in FIG. 3, the digital delay line according to the present invention includes unit delay elements comprising one NAND gate or one NOR gate. The NAND gate and the NOR gate are alternately arranged to form a delay line. In the drawing, clk and clkb are clock signals having a phase difference of 180° and sell to sel200 are signals for controlling delay time of the clock signals clk, clkb by digital delay line 300. The present embodiment shows a digital delay line comprising 200 unit delay elements.

According to the construction of the digital delay line of FIG. 3, the NAND gate ND200a has 2 input signals of clock signal clk and control signal sel200 and the output signal is provided as one input signal of NAND gate ND200b. A high level signal is provided as another input signal of the NAND gate ND200b. In the present embodiment, the unit delay element arranged most distant from output terminal clkout is the NAND gate ND200b, thereby high level signal is employed as one input signal. However, when the unit delay element arranged most distant from output terminal is NOR gate, low level signal is employed as one input signal. The output signal of NAND gate ND200b is provided to NOR gate NR199b, a unit delay element of next step. And, NOR gate NR199a has 2 input signals of clock signal clkb and control signal sel199 inverted by inverter IV199. The output signal of NOR gate NR199a and output signal of NAND gate ND200b are employed as 2 input signals of NOR gate NR199b. In this way, other NAND gates ND198a, ND198b, . . . ND4a, ND4b, ND2a, ND2b and other NOR gates NR197a, NR197b, . . . NR3a, NR3b, NR1a, NR1b are connected to other inverters IV197, . . . IV3, IV1. The output signal of NOR gate NR1b, the last unit delay element, is employed as output signal of digital delay line 300.

The rising edge of clock signal clk is the same time with the falling edge of clock signal clkb. In the unit delay element of digital delay line 300, NAND gate ND200b, . . . , ND2b and NOR gate NR199b, . . . , ND1b have the same delay time. And, NAND gate ND200a, . . . , ND2a and NOR gate NR199a, . . . , ND1a for providing clock signals clk, clkb to unit delay elements according to control signals sel200, . . . , sell have the same delay time. This is to have regular change of delay time according to selection signals sel200, . . . , sell. It is desirable that both clock signal clk and clock signal clkb have duty of 50% to obtain output signal clkout having a duty of 50%.

In the case that only selection signal sel2 is high level and that only selection signal sell is high level, the operation of digital delay line 300 will be described in the following. When only selection signal sel2 is high level, all the NAND gates ND200a, ND198a, . . . , ND4a output high level and all the NOR gates NR199a, NR197a, . . . , NR3a, NR1a output low level. And, high level input signal is provided to two input terminals of NAND gate Nd200b, thereby NAND gate ND200b outputs low level signal and low level signal is provided to two input terminals of NOR gate NR199b, thereby NOR gate NR199b outputs high level signal. With regard to selection signals sel200, . . . , sel3, all the NAND gates of unit delay element output low level signal and NOR gates output high level signal.

The NAND gate ND2a, to which selection signal sel2 is provided as an input signal, outputs inverted signal of clock signal clk. That is, when the clock signal clk is high level, NAND gate ND2a outputs low level signal and when the clock signal clk is low level, NAND gate ND2a outputs high level signal. The output signal of NAND gate ND2a is provided as one input signal of NAND gate ND2b and high level signal is provided from NOR gate NR4b, unit delay element of previous stage as another input signal of NAND gate ND2b. Therefore; NAND gate ND2b inverts output of NAND gate ND2a and provides the inverted output to NOR gate NR1b, unit delay element of next stage. The NOR gate NR1b inverts output signal of NAND gate ND2b and provides the inverted signal as output signal clkout of digital delay line 300 since a low level signal is outputted from NOR gate NR1a.

In the case that only selection signal sell is high level, all the NAND gates ND200a, ND198a, . . . , ND4a, ND2a output high level and NOR gates NR199a, NR197a, . . , NR3a output low level. With regard to selection signal sel200, . . . , sel2 all the NAND gates of unit delay element output low level signal and NOR gates output high level signal. The high level selection signal sell is inverted by inverter IV1 and provided as one input signal of NOR gate NR1a, thereby NOR gate outputs inverted signal of clock signal clkb and provides it to NOR gate NR1b. A low level signal is inputted from NAND gate ND2b as another input signal of NOR gate NR1b, thereby NOR gate NR1b again inverts output signal of NOR gate NR1a and provides the inverted signal as an output signal clkout of digital delay line 300.

When only control signal sel2 is high level, clock signal clk is outputted through 3 gates of NAND gate ND2a, NAND gate ND2b and NOR gate NR1b. However, when only control signal sell is high level, clock signal clkb is outputted through 2 gates of NOR gate NR1a and NOR gate NR1b. When the NAND gate and the NOR gate have the same delay time in the digital delay line 300, clock signals clk, clkb are inputted to digital delay line 300 and then, outputted as output signal clkout after a predetermined time corresponding to delay time in one gate.

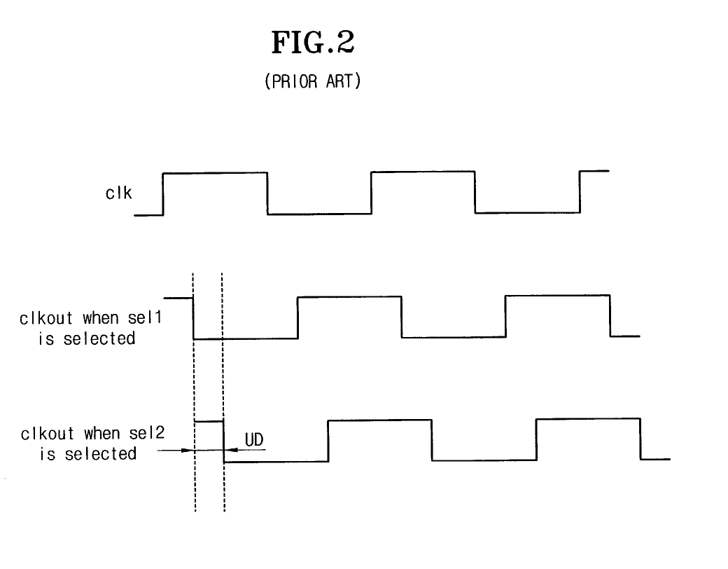

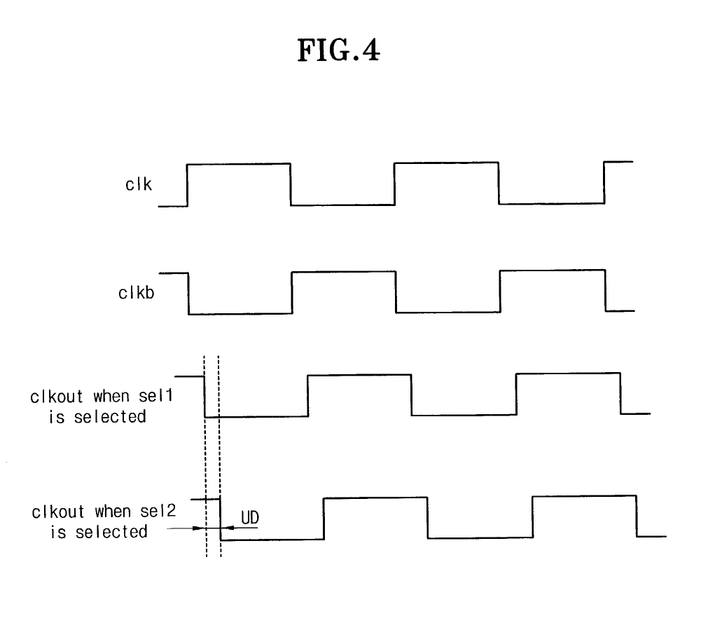

FIG. 4 is a waveform diagram explaining the operation of the digital delay line of FIG. 3 according to the present invention. The conventional digital delay line of FIG. 2 uses one clock signal clk, whereas the digital delay line according to the present invention uses two clock signals clk and clkb. As shown in FIG. 2, the first clock signal clk and the second clock signal clkb should have the phase difference of 180°, and have the duty of almost 50%. If the duty is not 50%, the unit delay time becomes irregular. Accordingly, the digital locked loop using the digital delay line according to the present invention is provided with a duty correction circuit in the front therof so that the clock signals clk and clkb have the duty of 50%.

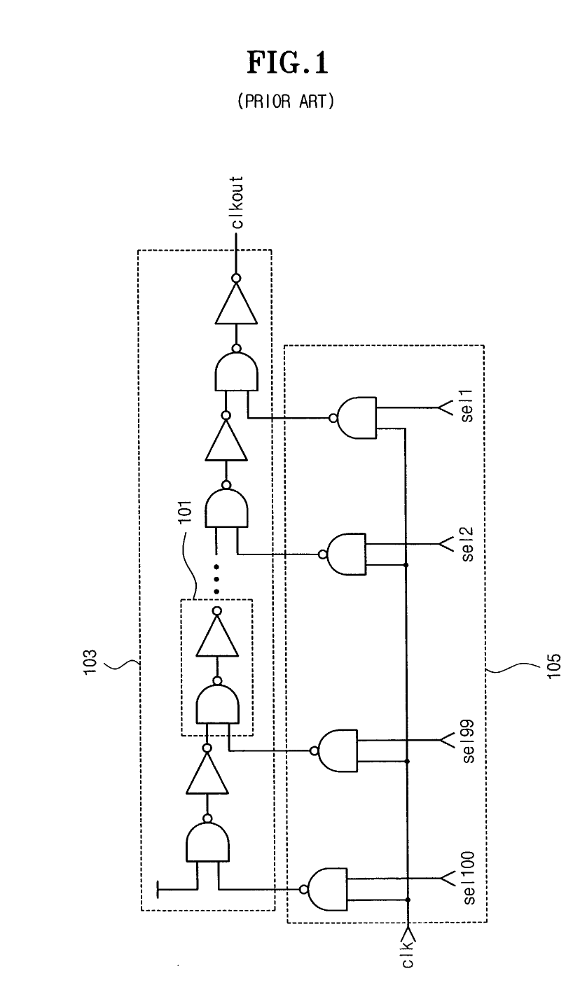

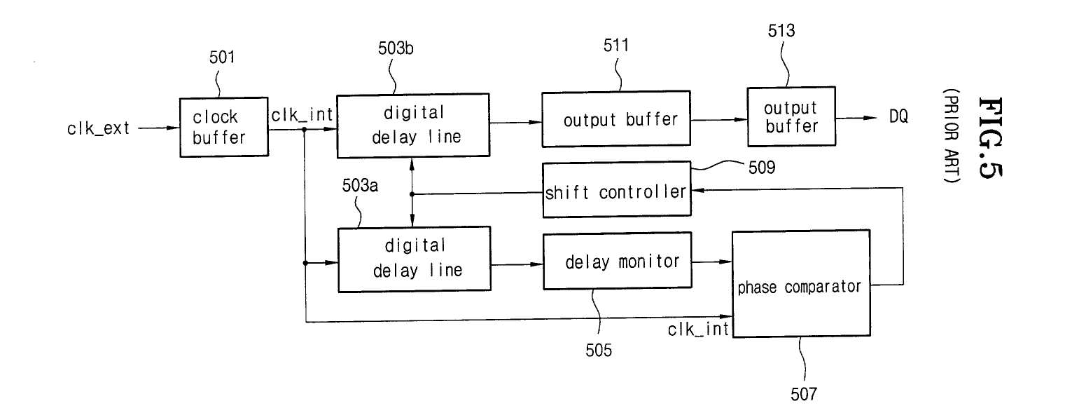

FIG. 5 is a block diagram of the conventional delay locked loop. As shown in FIG. 5, the conventional delay locked loop includes a clock buffer 501 for adjusting an external clock signal clk_ext inputted from the outside so as to suit a signal level of an internal circuit of the delay locked loop and and outputting the adjusted external clock signal as an internal clock signal clk_int. A digital delay line 503 operates to delay the internal clock signal clk_int as much as a delay time determined by a shift control circuit 509, and up to the present, the digital delay line having the construction of FIG. 1 has been used. A digital delay line 503a is for forming the delay locked loop, and a digital delay line 503b is for synchronizing data stored in a memory cell array and so on with the external clock signal clk_ext and outputting the synchronized data as output data DQ.

In FIG. 5, a delay monitoring circuit 505 performs a modeling of a delay time for the clock buffer 501, an output buffer 511, and an output driver 513. A phase comparison circuit 507 compares the phase of a signal obtained by passing the internal clock signal clk_int through the digital delay line 503a and the delay monitoring circuit 505 with the phase of the original internal clock signal clk_int, and output a signal that indicates the phase relation between the two signals. An output signal of the phase comparison circuit 507 is inputted to the shift control circuit 509, and converted into a signal for controlling a delay amount in the digital delay lines 503a and 503b to be inputted to the digital delay lines 503a and 503b.

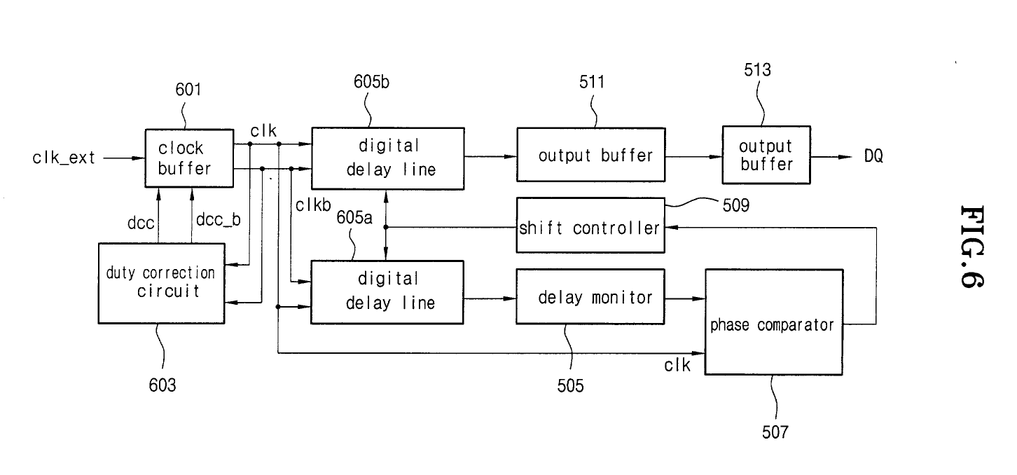

FIG. 6 is a block diagram of the delay locked loop according to an embodiment of the present invention. In distinction from the conventional delay locked loop of FIG. 5, the delay locked loop according to the present invention uses digital delay lines 605a and 605b having the construction of FIG. 3. Also, since the unit delay time becomes irregular if the duty is not 50%, a duty correction circuit 603 for correcting the duty of the clock signals clk and clkb outputted from the clock buffer 601 is provided in front of the delay locked loop according to the present invention. In FIG. 6, the construction and operation of the delay monitoring circuit 505, phase comparison circuit 507, shift control circuit 509, output buffer 511, and output driver 513 have already been described with reference to FIG. 5.

In FIG. 6, the clock buffer 601 receives the external clock signal clk_ext, and generates and outputs the first clock signal clk and the second clock signal having a signal level suitable for the internal circuit. The first clock signal clk and the second clock signal clkb have the phase difference of 180° from each other. As described above, since the unit delay time becomes regular only in the event that the first clock signal clk and the second clock signal clkb have the duty of 50%, the delay locked loop according to the present invention further includes the duty correction circuit 603 for correcting the duty of the first clock signal clk and the second clock signal clkb outputted from the clock buffer 601. The duty correction circuit 603 receives the first clock signal clk and the second clock signal clkb outputted from the clock buffer 601, generates and provides to the clock buffer 601 signals dcc and dcc_b for controlling the clock buffer 601 so that the clock buffer 601 has the duty of 50%. The first clock signal clk and the second clock signal clkb are selectively inputted to the digital delay lines 605a and 605b to be delayed for the predetermined time.

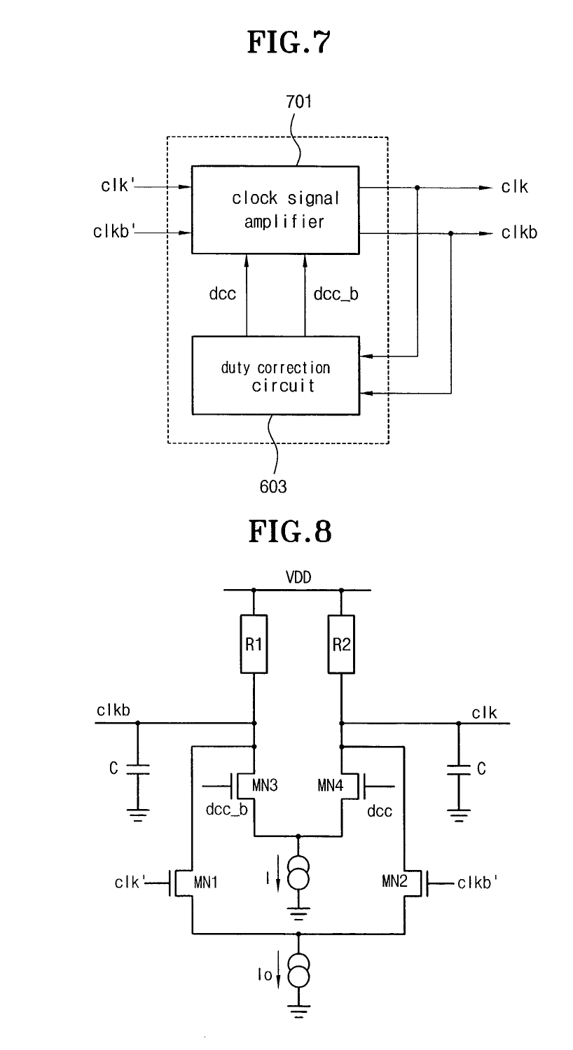

FIG. 7 is a view illustrating the relationship between a clock signal amplification section 701 that corresponds to a portion of the clock buffer 601 and a duty correction section 603. The clock buffer 601 includes a pre-amplification section (not illustrated) and a clock signal amplification section 701. The pre-amplification section receives the external clock signal clk_ext, and generates and outputs clock signals clk′ and clkb′. The clock signal amplification section 701 receives and re-amplifies the output signals clk′ and clkb′ of the pre-amplification section, and outputs the clock signals clk and clkb. The clock signals clk and clkb are provided to the digital delay line 605 and to the duty correction circuit 603 as well. The duty correction circuit 603 generates the signals dcc and dcc_b for controlling the clock signal amplification section 701 so as to correct the duty of the clock signals clk and clkb, and outputs the signals dcc and dcc_b to the clock signal amplification section 701.

FIG. 8 is a detailed circuit diagram of the clock signal amplification section 701. In FIG. 8, the ouput signals clk′ and clkb′ of the pre-amplification section are inputted to gates of NMOS transistors MN1 and MN2 which are driven by a current source To, respectively, and control the amount of current flowing through the NMOS transistors MN1 and MN2. The signals dcc and dcc_b outputted from the duty correction circuit 603 are inputted to gates of NMOS transistors MN3 and MN4 which are driven by a current source I, respectively, and control the amount of current flowing through the NMOS transistors MN3 and MN4. A power supply voltage VDD is applied to resistors R1 and R2. The amount of current flowing through the resistors R1 and R2 is controlled by the output signals clk′ and clkb′ of the pre-amplification section and the signals dcc and dcc_b of the duty correction circuit 603. The charging/discharging speed of capacitors C1 and C2 is changed according to the amount of current flowing through the resistors R1 and R2, and the voltages applied to the capacitors C1 and C2 are outputted as the output signals clk and clkb of the clock signal amplification section 701.

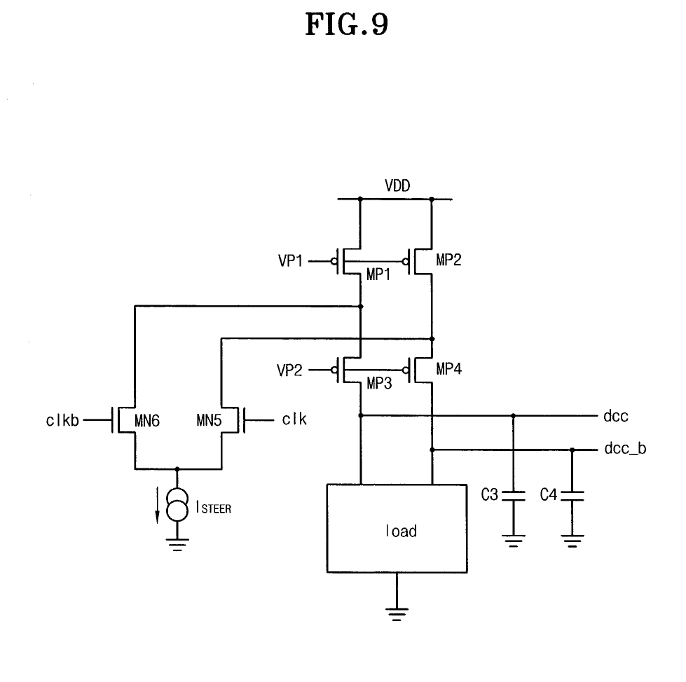

FIG. 9 is a detailed circuit diagram of the duty correction circuit 603. The output signals clk and clkb of the clock signal amplification section 701 are applied to gates of NMOS transistors MN5 and MN6 which are driven by a current source ISTEER, respectively, and control the current flow through the NMOS transistors MN5 and MN6. Since the amount of current charging/discharging in capacitors C3 and C4 is changed according to the duty of the clock signals clk and clkb, the voltage signals dcc and dcc_b applied to the capacitors C3 and C4, respectively, are determined according to the duty of the clock signals clk and clkb. If the clock signals clk and clkb have the duty of 50%, the signals dcc and dcc_b have a regular level. In FIG. 9, a voltage signal VP1 is applied to gates of PMOS transistors MP1 and MP2, and a voltage signal VP2 is applied to gates of PMOS transistors MP3 and MP4. The amount of current flowing through the PMOS transistors MP1, MP2, MP3, and MP4 is controlled according to the level of the voltage signals VP1 and VP2.

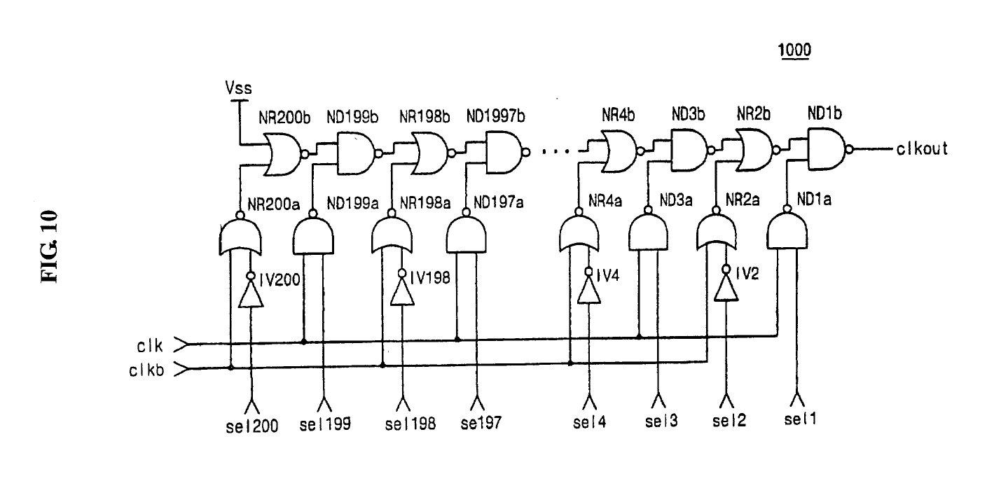

FIG. 10 is a circuit diagram of digital delay line according to another embodiment of the present invention. It is different from the digital delay line in FIG. 3 only in that a first unit delay element is composed of NOR gates and one input signal provided from the external to the NOR gate is ground level Vss.

As described above, the present invention has the advantages in that the jitter characteristic of the delay locked loop is improved, and the area required for designing the digital delay line is reduced about by one-half in comparison to conventional existing digital delay lines. Also, according to the present invention, since the unit delay time can be more shortened, a more elaborate delay locked loop can be made.

Although a preferred embodiment of the present invention has been described for illustrative purposes, those skilled in the art will appreciate that various modifications, alterations, additions and substitutions are possible, without departing from the scope and spirit of the invention as disclosed in the accompanying claims.

What is claimed is:

1. A digital delay line comprising:
a first NAND gate for 2 input of first clock signal and first control signal;
a second NAND gate for 2 input of output signal of the first NAND gate and high level signal;
a first inverter for input of second control signal;
a first NOR gate for 2 input of second clock signal having a phase difference with the first clock signal and output signal of the first inverter; and
a second NOR gate for 2 input of output signal of the second NAND gate and output signal of the first NOR gate.

2. The digital delay line of claim 1, further comprising:
a third NAND gate for 2 input of first clock signal and a third control signal; and
a fourth NAND gate for 2 input of output signal of the third NAND gate and output signal of the second NOR gate.

3. The digital delay line of claim 2, further comprising:
a second inverter for input of fourth control signal;
a third NOR gate for 2 input of the second clock signal and output signal of the second inverter; and
a fourth NOR gate for 2 input of output signal of the fourth NAND gate and output signal of the third NOR gate.

4. The digital delay line of claim 1, wherein the rising edge of the first clock signal is the same time with the falling edge of the second clock signal.

5. The digital delay line of claim 1, wherein both the first clock signal and the second clock signal have a duty of 50%.

6. The digital delay line of claim 1, wherein the second NAND gate and the second NOR gate have the same delay time.

7. The digital delay line of claim 6, wherein the first NAND gate and the first NOR gate have the same delay time.

8. A digital delay line comprising:
a first inverter for input of first control signal;
a first NOR gate for 2 input of the first clock signal and output signal of the first inverter;
a second NOR gate for 2 input of output signal of the first NOR gate and low level signal;
a first NAND gate for 2 input of second clock signal having a phase difference of 180° with the first clock signal and a second control signal; and
a second NAND gate for 2 input of output signal of the first NAND gate and output signal of the second NOR gate.
